(19) United States
(12) Patent Application Publication
(10) Pub. No.: US 2026/0190593 A1
(43) Pub. Date: Jul. 2, 2026

(54) DISPLAY DEVICE AND METHOD OF MANUFACTURING THE SAME

(71) Applicant: LG Display Co., Ltd., Seoul (KR)

(72) Inventors: Sunghwan YOON, Seoul (KR); Kanghyun KIM, Paju-si (KR)

(73) Assignee: LG Display Co., Ltd., Seoul (KR)

(21) Appl. No.: 19/201,731

(22) Filed: May 7, 2025

(30) Foreign Application Priority Data
Dec. 30, 2024 (KR) 10-2024-0200064

(51) Int. Cl. H10H 29/85; H01L 25/075; H10H 29/01; H10H 29/24; H10H 29/80

(52) U.S. Cl. CPC H10H 29/857; H10H 29/034; H10H 29/0364; H10H 29/24; H10H 29/842; H10W 90/00

(57) ABSTRACT

A display device is formed by placing a plurality of pixel units. Each of the plurality of pixel units includes a body unit having an accommodation groove and a plurality of holes extending through a bottom surface of the accommodation groove, a plurality of light emitting diodes disposed in the accommodation groove, and a plurality of pixel pads on a rear surface of the body unit. The pixel pads are electrically connected to the plurality of light emitting diodes through the plurality of holes, and each light emitting diode overlaps an area between adjacent holes. By locating the light emitting diodes on the front surface of the body unit and forming the pixel pads on the rear surface, the structure of the front surface, which serves as an emission surface, is simplified. This configuration enables improved display integration and supports a high-resolution and narrow-bezel design.

### CROSS-REFERENCE TO RELATED APPLICATIONS

This application claims the priority of Korean Patent Application No.10-2024-0200064 filed on Dec. 30, 2024, in the Korean Intellectual Property Office, the disclosure of which is incorporated herein by reference.

### BACKGROUND

### Technical Field

The present disclosure relates to a display device and a method of manufacturing the same, and more particularly to, a display device using a light emitting diode (LED) and a method of manufacturing the same.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

The disclosure relates to a display device formed by arranging a plurality of pixel units, each including a body with an accommodation groove and through-holes connecting to rear-side pixel and common pads. Inorganic light emitting diodes (LEDs) are disposed in the groove and self-assembled into shaped assembly holes by applying an electric field between opposing assembly electrodes formed along the inner walls of the holes. Each LED, such as red, green, or blue, has a distinct planar shape corresponding to its designated assembly hole, allowing accurate placement without complex alignment. Electrical connections between the rear-side pads and front-side LEDs are made through connection holes, simplifying the emission surface by removing visible electrodes.

This configuration enables a high-resolution, narrow-bezel display and allows the overall display size and shape to vary based on the number and arrangement of pixel units. The manufacturing method improves process efficiency and placement accuracy by eliminating the need for LED transfer and alignment steps, while the use of inorganic LEDs offers enhanced luminous efficiency and reliability.

Various embodiments of the present disclosure provide a display device which includes an inorganic light emitting diode with improved luminous efficiency to be driven at a low power and a manufacturing method of a display device.

Various embodiments of the present disclosure provide a display device which is formed by placing a plurality of pixel unit and a manufacturing method of a display device.

Various embodiments of the present disclosure provide a display device which is configured in various shapes depending on the number of a plurality of pixel units and a placement thereof and a manufacturing method of a display device.

Various embodiments of the present disclosure provide a display device in which a light emitting diode is self-assembled and a manufacturing method of a display device.

Various embodiments of the present disclosure provide a display device with a high resolution in which a bezel is reduced or minimized and a manufacturing method of a display device.

Technical benefits of the present disclosure are not limited to the above-mentioned benefits, and other benefits, which are not mentioned above, can be clearly understood by those skilled in the art from the following descriptions.

According to an aspect of the present disclosure, a display device is a display device which is formed by placing a plurality of pixel units and includes each of the plurality of pixel units includes a body unit which has an accommodation groove and a plurality of holes extending through a bottom surface of the accommodation groove, a plurality of light emitting diodes disposed in the accommodation groove, and a plurality of pixel pads which is disposed on a rear surface of the body unit and is connected to each of the plurality of light emitting diodes in an area of the plurality of holes and the plurality of light emitting diode overlaps an area between the plurality of holes. Accordingly, the plurality of light emitting diodes is disposed on the front surface of the body unit and the plurality of pixel pads is formed on a rear surface of the body unit to simplify a structure of the front surface of the body unit which is an emission surface.

According to an aspect of the present disclosure, a manufacturing method of a display device includes a step of forming a body unit having a plurality of first holes, a plurality of second holes, and an accommodation groove by processing a substrate, a step of forming a first assembly electrode and a second assembly electrode in inner surfaces of the plurality of first holes and the plurality of second holes of the body unit, respectively, a step of forming a first planarization layer having a plurality of assembly holes in the accommodation groove, a step of self-assembling the plurality of light emitting diodes in the plurality of assembly holes by applying a voltage to the first assembly electrode and the second assembly electrode, and a step of forming a plurality of pixel pads and a common pad on a rear surface of the body unit. Accordingly, the light emitting diode may be easily self-assembled in the assembly hole using the plurality of assembly electrodes.

Other detailed matters of the exemplary embodiments are included in the detailed description and the drawings.

According to the present disclosure, a high resolution display device which includes an inorganic light emitting diode with excellent luminous efficiency to display an image with a high efficiency and a high luminance at a low power and a manufacturing method of a display device may be implemented.

According to the present disclosure, a display device formed by placing a plurality of pixel units may be easily formed.

According to the present disclosure, the display device may be formed in various shapes depending on the number of the plurality of pixel units and a placement thereof.

According to the present disclosure, the light emitting diode is self-assembled to simplify a transfer process of the light emitting diode.

According to the present disclosure, a display device with a high resolution in which a bezel is reduced or minimized and a manufacturing method of a display device may be provided.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an exemplary embodiment of the present disclosure;

FIG. 2 is a plan view of a pixel unit of a display device according to an exemplary embodiment of the present disclosure;

FIG. 3 is a rear view of a pixel unit of a display device according to an exemplary embodiment of the present disclosure;

FIG. 4 is a cross-sectional view taken along IV-IV′ of FIG. 2;

FIG. 5 is a cross-sectional view taken along the line V-V′ of FIG. 2; and

FIGS. 6A to 6I are process diagrams for explaining a method of manufacturing a pixel unit of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to accompanying drawings.

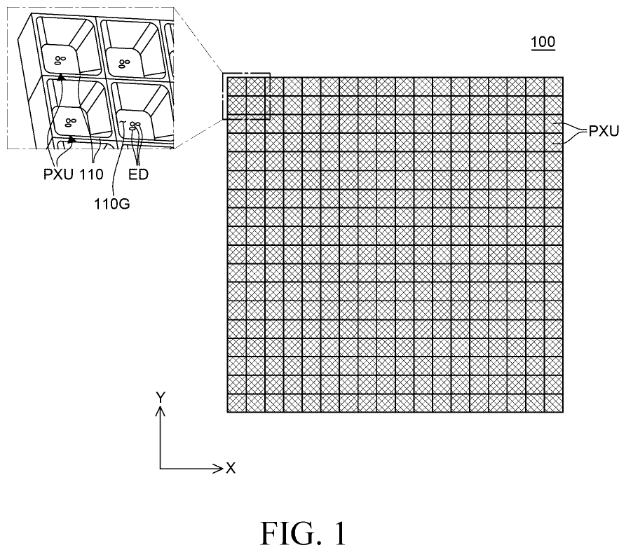

FIG. 1 is a schematic plan view of a display device according to an exemplary embodiment of the present disclosure.

Referring to FIG. 1, a display device 100 includes a plurality of pixel units PXU. The plurality of pixel units PXU is disposed in a matrix to configure the display device 100. The plurality of pixel units PXU is connected to form one display device 100. Each of the plurality of pixel units PXU includes a plurality of light emitting diodes ED to display images.

A shape and a size of the display device 100 may be configured in various forms depending on the number of the plurality of pixel units PXU and a placement thereof. For example, the larger the size of the display device 100, the more the number of pixel units PXU is disposed to form the display device 100. For example, a ratio and a shape of the display device 100 may vary depending on the number and placement of the pixel units PXU in a first direction X or a second direction Y. Accordingly, as the display device 100 is configured by placing a module type pixel units PXU, the display device 100 is formed in various shapes and a degree of freedom of design may be improved.

In the meantime, even though it is not illustrated in the drawing, a circuit board may be disposed on rear surfaces of the plurality of pixel units PXU. The circuit board is in contact with a common pad CP and a plurality of pixel pads PP on rear surfaces of the plurality of pixel units PXU to apply a voltage thereto.

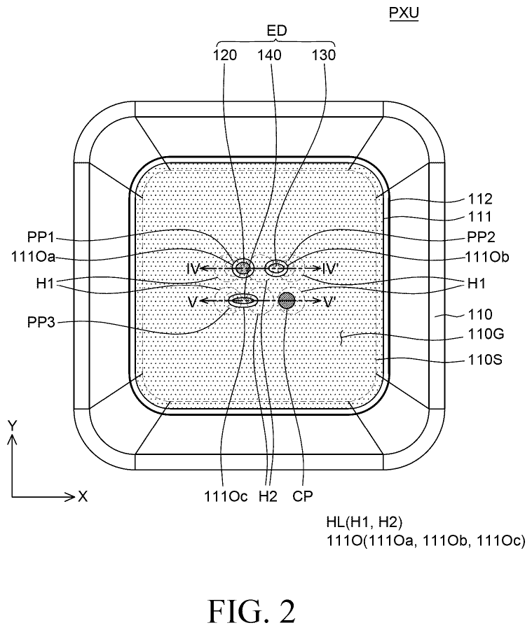

Hereinafter, a plurality of pixel units PXU will be described in more detail with reference to FIGS. 2 to 5.

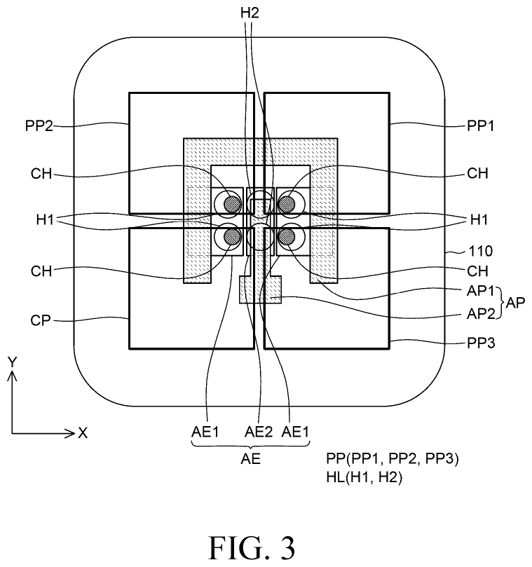

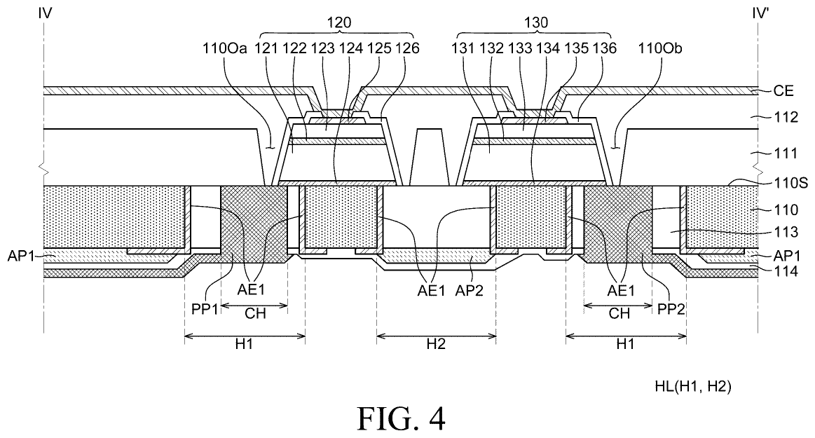

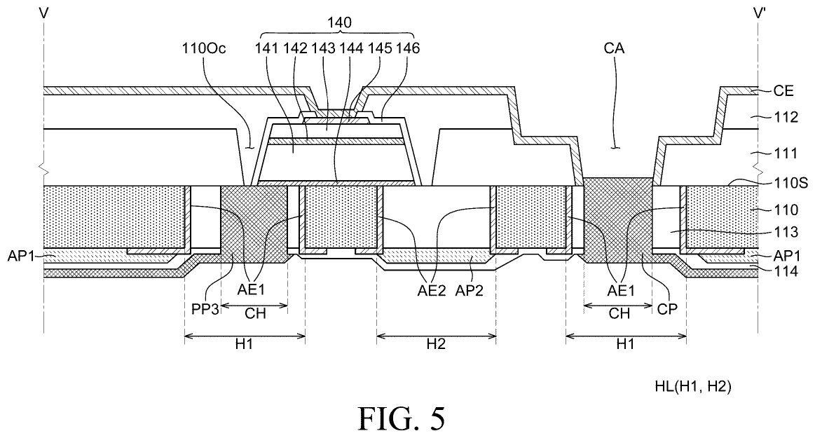

FIG. 2 is a plan view of a pixel unit of a display device according to an exemplary embodiment of the present disclosure. FIG. 3 is a rear view of a pixel unit of a display device according to an exemplary embodiment of the present disclosure. FIG. 4 is a cross-sectional view taken along IV-IV′ of FIG. 2. FIG. 5 is a cross-sectional view taken along the line V-V′ of FIG. 2. For the convenience of description, in FIG. 2, hatching of a second planarization layer 112 is omitted and the second planarization layer 112 is illustrated with a thick solid line. In FIG. 3, hatches of the plurality of pixel pads PP and the common pad CP are omitted and the plurality of pixel pads PP and the common pad CP are illustrated with thick solid lines.

Referring to FIGS. 2 to 5, each of the plurality of pixel units PXU includes a body unit 110, a first planarization layer 111, a second planarization layer 112, a filling layer 113, a passivation layer 114, a plurality of light emitting diodes ED, a common electrode CE, a plurality of assembly electrodes AE, a plurality of assembly pads AP, a plurality of pixel pads PP, and a common pad CP.

First, the body unit 110 is a frame which forms the pixel unit PXU. The body unit 110 may include an accommodation groove 110G which is concavely formed. The body unit 110 may be configured by the accommodation groove 110G, a side wall part which encloses a side surface of the accommodation groove 110G, and a bottom part which configures a bottom surface 110S of the accommodation groove 110G. The body unit 110 may be formed of an insulating material having a rigidity. For example, the body unit 110 may be formed by processing a glass substrate.

A plurality of holes HL is formed in the body unit 110. The plurality of holes HL may be formed to extend through the bottom surface 110S. The plurality of holes HL is holes HL in which a plurality of assembly electrodes AE used to self-assemble the light emitting diode ED is disposed. Further, the common pad CP and the plurality of pixel pads PP may be formed in the plurality of holes HL.

The plurality of holes HL includes a plurality of first holes H1 in which the first assembly electrodes AE1 are formed and a plurality of second holes H2 in which a second assembly electrodes AE2 are formed. For example, the plurality of first holes H1 is disposed in a matrix according to the first direction X and the second direction Y and the plurality of second holes H2 may be disposed along the second direction Y. Further, the plurality of first holes H1 and the plurality of second holes H2 may be alternately disposed along the first direction X. For example, in one body unit 110, six holes HL which is disposed in two rows and three columns are formed and the plurality of first holes H1 is disposed in a first column and a third column and the plurality of second holes H2 may be disposed in a second column.

Referring to FIG. 2, the plurality of light emitting diodes ED is disposed in the accommodation groove 110G of the body unit 110. The plurality of light emitting diodes ED may be any one of a light-emitting diode (LED) or a micro light-emitting diode (micro LED), but the exemplary embodiments of the present disclosure are not limited thereto. The plurality of light emitting diodes ED includes a first light emitting diode 120, a second light emitting diode 130, and a third light emitting diode 140. For example, the first light emitting diode 120 is a red light emitting diode ED, the second light emitting diode 130 is a green light emitting diode ED, and the third light emitting diode 140 is a blue light emitting diode ED.

The plurality of light emitting diodes ED may be disposed in an area between the first hole H1 and the second hole H2. The plurality of light emitting diodes ED is disposed in an area between the plurality of holes HL and overlaps the first hole H1 and the second hole H2. For example, the first light emitting diode 120 is disposed between a first hole H1 in a first row and a first column and a second hole H2 in a first row and a second column. The second light emitting diode 130 is disposed between a second hole H2 in a first row and a second column and a first hole H1 in a first row and a third column. The third light emitting diode 140 may be disposed between a first hole H1 in a second row and a first column and a second hole H2 in a second row and a second column.

Referring to FIG. 4, the first light emitting diode 120 includes a first n-type semiconductor layer 121, a first emission layer 122, a first p-type semiconductor layer 123, a first n-type electrode 124, a first p-type electrode 125, and a first protection film 126.

The first n-type semiconductor layer 121 is disposed on the bottom surface 110S of the accommodation groove 110G and the first p-type semiconductor layer 123 is disposed on the first n-type semiconductor layer 121. The first n-type semiconductor layer 121 and the first p-type semiconductor layer 123 may be semiconductor layers doped with n-type and p-type impurities. For example, the first n-type semiconductor layer 121 and the first p-type semiconductor layer 123 may be layers doped with n-type and p-type impurities into a material such as gallium nitride (GaN), indium aluminum phosphide (InAlP), or gallium arsenide (GaAs). Further, the p-type impurity may be magnesium (Mg), zinc (Zn), and beryllium (Be), and the n-type impurity may be silicon (Si), germanium, and tin (Sn), but is not limited thereto.

The first emission layer 122 is disposed between the first n-type semiconductor layer 121 and the first p-type semiconductor layer 123. The first emission layer 122 may emit light by a driving current. The first emission layer 122 may be formed with a single layer or a multi-quantum well (MQW) structure, and for example, may be formed of indium gallium nitride (InGaN) or gallium nitride (GaN), but is not limited thereto.

The first n-type electrode 124 is disposed on a bottom surface of the first n-type semiconductor layer 121 and the first p-type electrode 125 is disposed on a top surface of the first p-type semiconductor layer 123. The first n-type electrode 124 and the first p-type electrode 125 may be electrically connected to the common electrode CE and the first pixel pad PP1, respectively. For example, the first n-type electrode 124 is formed of an opaque conductive material, such as titanium (Ti), gold (Au), silver (Ag), copper (Cu), or an alloy thereof and the first p-type electrode 125 may be formed of a transparent conductive material, such as indium tin oxide (ITO) or indium zinc oxide (IZO). Further, at least one of the first n-type electrode 124 and the first p-type electrode 125 may include a ferromagnetic material, such as nickel (Ni), for self-assembly process.

Next, the first protection film 126 which encloses the first n-type semiconductor layer 121, the first emission layer 122, the first p-type semiconductor layer 123, the first n-type electrode 124, and the first p-type electrode 125 is disposed. The first protection film 126 is formed of an insulating material to protect the first n-type semiconductor layer 121, the first emission layer 122, and the first p-type semiconductor layer 123. For example, the first protection film 126 is formed of an insulating material, such as silicon oxide (SiOx) or silicon nitride (SiNx), but is not limited thereto.

The second light emitting diode 130 includes a second n-type semiconductor layer 131, a second emission layer 132, a second p-type semiconductor layer 133, a second n-type electrode 134, a second p-type electrode 135, and a second protection film 136.

The second n-type semiconductor layer 131, the second p-type semiconductor layer 133, the second n-type electrode 134, the second p-type electrode 135, and the second protection film 136 of the second light emitting diode 130 may be substantially the same as the first n-type semiconductor layer 121, the first p-type semiconductor layer 123, the first n-type electrode 124, the first p-type electrode 125, and the first protection film 126 of the first light emitting diode 120, respectively.

However, the second emission layer 132 of the second light emitting diode 130 may emit different color light from the first emission layer 122 of the first light emitting diode 120. Further, a planar shape of the first light emitting diode 120 is a circle and a planar shape of the second light emitting diode 130 may be an oval. A planar shape of the first n-type semiconductor layer 121 and the first p-type semiconductor layer 123 is a circle and planar shape of the second n-type semiconductor layer 131 and the second p-type semiconductor layer 133 is an oval.

Referring to FIG. 5, the third light emitting diode 140 includes a third n-type semiconductor layer 141, a third emission layer 142, a third p-type semiconductor layer 143, a third n-type electrode 144, a third p-type electrode 145, and a third protection film 146.

The third n-type semiconductor layer 141, the third p-type semiconductor layer 143, the third n-type electrode 144, the third p-type electrode 145, and the third protection film 146 of the third light emitting diode 140 may be substantially the same as the first n-type semiconductor layer 121, the first p-type semiconductor layer 123, the first n-type electrode 124, the first p-type electrode 125, and the first protection film 126 of the first light emitting diode 120, respectively.

However, the third emission layer 142 of the third light emitting diode 140 may emit different color light from the first emission layer 122. Further, a planar shape of the first light emitting diode 120 is a circle and a planar shape of the third light emitting diode 140 may be an oval. Further, both the planar shape of the second light emitting diode 130 and the planar shape of the third light emitting diode 140 are an oval and the third light emitting diode 140 may have an oval shape having a major axis longer than a major axis of the planar shape of the second light emitting diode 130.

In the display device 100 according to the exemplary embodiment of the present disclosure, the first light emitting diode 120, the second light emitting diode 130, and the third light emitting diode 140 are configured to have different shapes, respectively, to distinguish the plurality of light emitting diodes ED. For example, when the light emitting diode ED is self-assembled, the plurality of light emitting diodes ED is formed to have different shapes and the light emitting diode ED is self-assembled in only an assembly hole 111O having a shape corresponding to each of the plurality of light emitting diodes ED. However, the shapes of the plurality of light emitting diodes ED are illustrative, so that it is not limited thereto.

In the meantime, the light emitting diode ED is mainly disposed on a front surface of the body unit 110 which is an emission surface, that is, on the accommodation groove 110G of the body unit 110. Further, electrodes, such as the pixel pad PP or the assembly pad AP are located on a rear surface of the body unit 110 so that the electrodes are not visible from the emission surface. Therefore, the structure of the emission surface may be simplified and degradation of the luminous efficiency due to the complex structure may be suppressed.

Referring to FIGS. 4 and 5, the first planarization layer 111 is disposed on the bottom surface 110S of the body unit 110. The first planarization layer 111 is disposed so as to cover the bottom surface 110S and may planarize an upper portion of the accommodation groove 110G. The first planarization layer 111 may be configured by a single layer or a double layer, and for example, may be formed of photoresist or an acrylic-based organic material, but is not limited thereto.

The first planarization layer 111 includes a plurality of assembly holes 111O which overlaps the plurality of light emitting diodes ED. For example, the plurality of assembly holes 111O may include a first assembly hole 111Oa, a second assembly hole 111Ob, and a third assembly hole 111Oc. The first assembly hole 111Oa has a circular shape corresponding to the planar shape of the first light emitting diode 120. The second assembly hole 111Ob has an oval shape corresponding to the planar shape of the second light emitting diode 130. The third assembly hole 111Oc has an oval shape corresponding to the planar shape of the third light emitting diode 140. Each of the plurality of assembly holes 111O has a shape corresponding to a specific light emitting diode ED so that only a specified type of light emitting diode ED may be seated in each of the assembly holes 111O.

The second planarization layer 112 is disposed on the first planarization layer 111. The second planarization layer 112 is disposed so as to cover the plurality of light emitting diodes ED to fix and protect the plurality of light emitting diodes ED. The second planarization layer 112 may be configured by a single layer or a double layer, and for example, may be formed of photoresist or an acrylic-based organic material, but is not limited thereto.

The common electrode CE is disposed on the second planarization layer 112. The common electrode CE may be disposed on the front surface of the second planarization layer 112. The common electrode CE may be commonly electrically connected to the P-type electrodes of the plurality of light emitting diodes ED through a contact hole of the second planarization layer 112. Further, the common electrode CE is connected to the common pad CP in a contact area CA from which the second planarization layer 112 and the first planarization layer 111 are partially removed to be applied with a common signal. For example, the common electrode CE may be formed of a transparent conductive material, such as indium tin oxide (ITO) or indium zinc oxide (IZO), but is not limited thereto.

At this time, the contact area CA is an area from which the first planarization layer 111 and the second planarization layer 112 are removed to expose the common pad CP and the common electrode CE and the common pad CP may be connected in the contact area CA.

Referring to FIGS. 3 to 5, a plurality of assembly electrodes AE is disposed on a rear surface of the body unit 110. Further, the plurality of assembly electrodes AE is disposed so as to overlap the plurality of holes HL so that at least some of the assembly electrodes may be disposed on an inner surface of the hole HL. For example, a part of the assembly electrode AE is disposed on a rear surface of the body unit 110 and the other part may be disposed along an inner surface of the hole HL.

The plurality of assembly electrodes AE includes a first assembly electrode AE1 and a second assembly electrode AE2. The first assembly electrode AE1 is disposed in the plurality of first holes H1 and the second assembly electrode AE2 is disposed in the plurality of second holes H2. The first assembly electrode AE1 and the second assembly electrode AE2 may be disposed to be adjacent to each other. The light emitting diode ED may be self-assembled in an area between the first assembly electrode AE1 and the second assembly electrode AE2, that is, an area between the first hole H1 and the second hole H2, by an electric field formed between the first assembly electrode AE1 and the second assembly electrode AE2. For example, one first assembly electrode AE1 overlaps the plurality of first holes H1 in the first column, one second assembly electrode AE2 overlaps the plurality of second holes H2 in the second column, and the other first assembly electrode AE1 may overlap a plurality of first holes H1 in the third column.

The filling layer 113 which is an insulating material is disposed in the plurality of holes HL. The filling layer 113 may be filled in the plurality of holes H. The filling layer 113 may cover the assembly electrode AE which covers inner surfaces of the plurality of holes HL. The assembly electrode AE may be disposed between the filling layer 113 and the inner surfaces of the plurality of holes HL. The filling layer 113 which is disposed so as to fill the plurality of holes HL may configure one plane with the bottom surface 110S of the accommodation groove 110G. The filling layer 113 may support a part of the light emitting diode ED which overlaps the plurality of holes HL together with the bottom surface 110S and a part of the first planarization layer 111. Further, the filling layer 113 may support a part of the assembly pad AP, the passivation layer 114, the common pad CP, and the pixel pad PP which overlap the plurality of holes HL together with the rear surface of the body unit 110.

The plurality of assembly pads AP is disposed on the rear surface of the body unit 110. The assembly pad AP is a pad electrode which applies a voltage to the assembly electrode AE. For example, during the self-assembly process of the light emitting diode ED, the assembly pad AP is connected to a power source to apply a voltage to the assembly pad AP and the assembly electrode AE. The assembly pad AP overlaps at least a part of the plurality of holes HL and the filling layer 113 and may be in contact with a part of the assembly electrode AE located on the rear surface of the body unit 110.

The assembly pad AP includes a first assembly pad AP1 and a second assembly pad AP2. The first assembly pad AP1 overlaps a part of each of the plurality of first holes H1 and may be connected to the first assembly electrode AE1. The second assembly pad AP2 overlaps a part of each of the plurality of second holes H2 and may be connected to the second assembly electrode AE2.

The passivation layer 114 is disposed on the rear surface of the body unit 110. The passivation layer 114 may cover the plurality of assembly pads AP and the plurality of assembly electrodes AE located on the rear surface of the body unit 110. The passivation layer 114 is an insulating layer which insulates the common pad CP and the pixel pad PP from the plurality of assembly pads AP and the plurality of assembly electrodes AE. For example, the passivation layer 114 may be formed of an insulating material, such as silicon oxide (SiOx) or silicon nitride (SiNx), but is not limited thereto.

Referring to FIGS. 3 and 5, the common pad CP is disposed on the passivation layer 114. The common pad CP is a pad electrode which applies a voltage to the common electrode CE. An area of the first hole H1 which does not overlap the light emitting diode ED, among the plurality of first holes H1, may be used as a path to connect the common pad CP and the common electrode CE. For example, three first holes H1, among four first holes H1, overlap the first light emitting diode 120, the second light emitting diode 130, and the third light emitting diode 140 and the remaining one hole HL does not overlap the light emitting diode ED. In an area of the first hole H1 which does not overlap the light emitting diode ED, a connection hole CH may be formed in the passivation layer 114 and the filling layer 113. The common pad CP is disposed so as to cover the connection hole CH and the first hole H1 and may be filled in the connection hole CH. The connection hole CH and the common pad CP may overlap a contact area CA from which the first planarization layer 111 and the second planarization layer 112 are partially removed. The common pad CP protrudes from the connection hole CH more than the bottom surface 110S of the accommodation groove 110G and may be connected to the common electrode CE. The common pad CP protrudes from the connection hole CH toward the accommodation groove 110G to be connected to the common electrode CE. Accordingly, the common pad CP is electrically connected to the common electrode CE formed on the front surface of the accommodation groove 110G through the connection hole CH.

Referring to FIGS. 3 to 5, the plurality of pixel pads PP is disposed on the passivation layer 114. The plurality of pixel pads PP is pad electrodes which apply a voltage to n-type electrodes of the plurality of light emitting diodes ED. The plurality of pixel pads PP includes a first pixel pad PP1, a second pixel pad PP2, and a third pixel pad PP3. The first pixel pad PP1 is connected to the first n-type electrode 124 of the first light emitting diode 120. The second pixel pad PP2 is connected to the second n-type electrode 134 of the second light emitting diode 130. The third pixel pad PP3 is connected to the third n-type electrode 144 of the third light emitting diode 140.

The first hole H1 which overlaps the light emitting diode ED, among the plurality of first holes H1 may be used as a connection path between the light emitting diode ED and the pixel pad PP. For example, three first holes H1, among four first holes H1, may overlap the first light emitting diode 120, the second light emitting diode 130, and the third light emitting diode 140. Further, in the area of three first holes H1, a connection hole CH which passes through the filling layer 113 and the passivation layer 114 may be formed. The plurality of connection holes CH may be disposed to be biased toward the plurality of light emitting diodes ED in the plurality of first holes H1. The connection hole CH may overlap each of the plurality of light emitting diodes ED and the n-type electrodes of the plurality of light emitting diodes ED may be exposed through the connection hole CH. The plurality of pixel pads PP is disposed so as to cover the connection hole CH and the first hole H1 and may be filled in the connection hole CH. Accordingly, the plurality of pixel pads PP may be connected to the n-type electrode of the light emitting diode ED through the connection hole CH.

The rear surface of the body unit 110 is divided into four areas and the common pad CP and the plurality of pixel pads PP are formed in each of four areas to easily connect the common pad CP and the plurality of pixel pads PP and the circuit board. At this time, sizes of the common pad CP and the plurality of pixel pads PP may be formed to be larger than the size of at least the plurality of holes HL. The common pad CP and the pixel pads PP may extend from the plurality of holes HL toward an edge of the body unit 110. For example, the common pad CP and the plurality of pixel pads PP are formed to have a size to cover the most of the rear surface of the body unit 110 to easily contact with the circuit board.

In the meantime, when the pixel unit PXU of the display device 100 according to the exemplary embodiment of the present disclosure is manufactured, the plurality of light emitting diodes ED is self-assembled using an electric field and the pixel unit PXU may be more easily formed. As the plurality of light emitting diodes ED is self-assembled in the assembly hole 111O of the first planarization layer 111, an alignment error of the plurality of light emitting diodes ED may be reduced and a process time may be shortened.

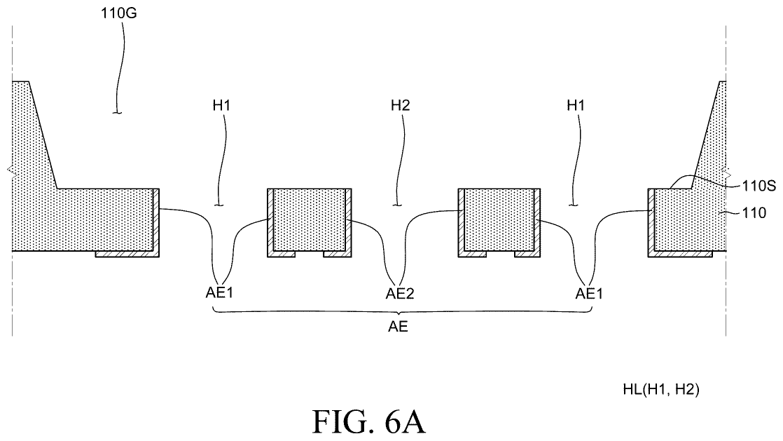

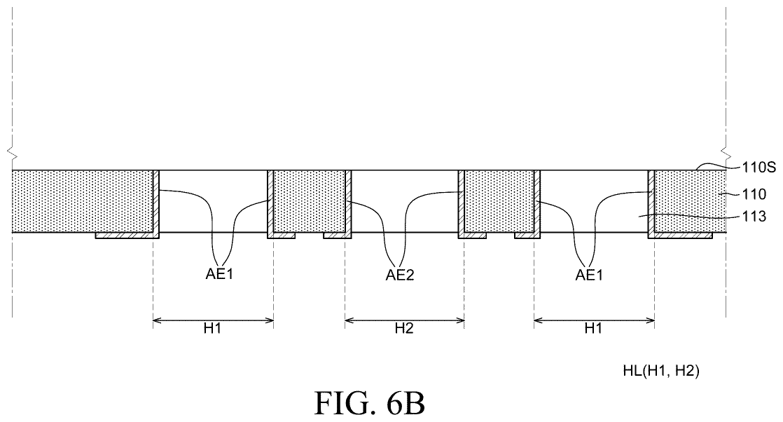

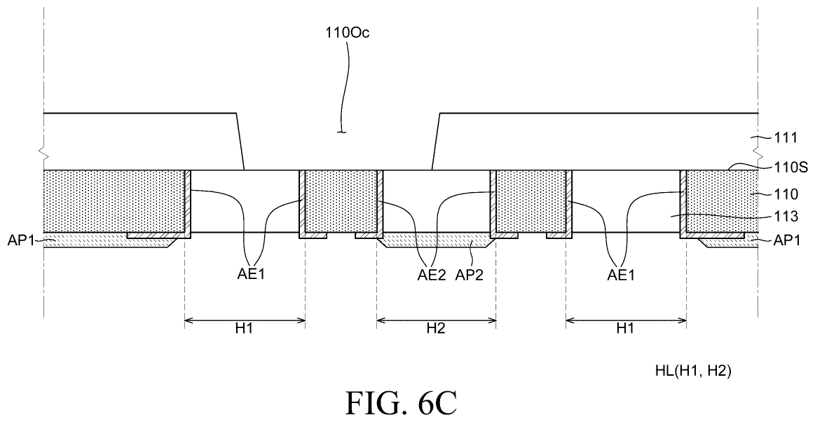

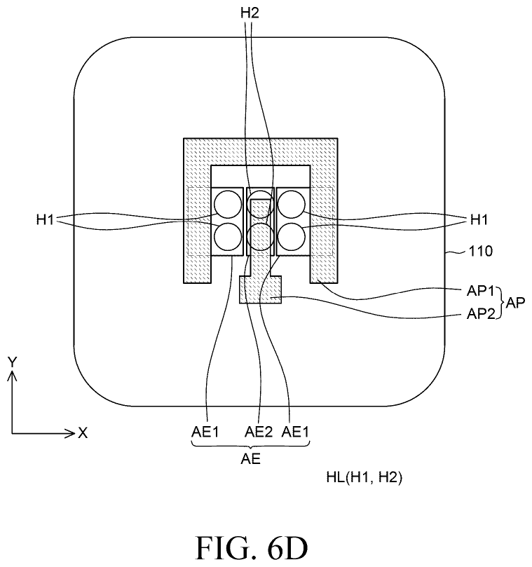

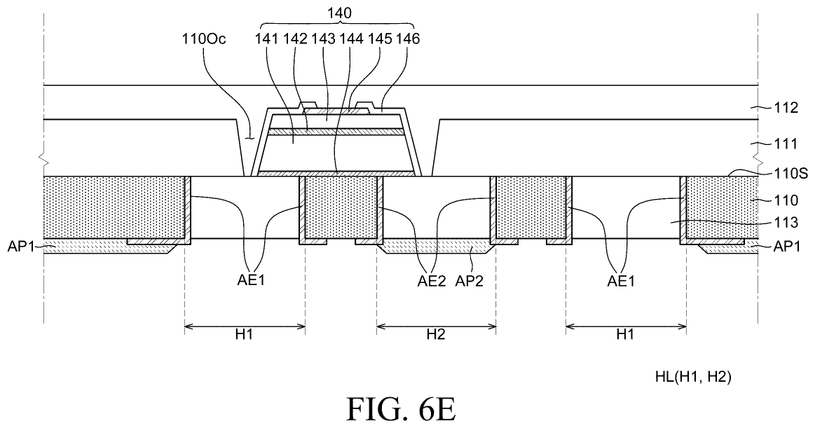

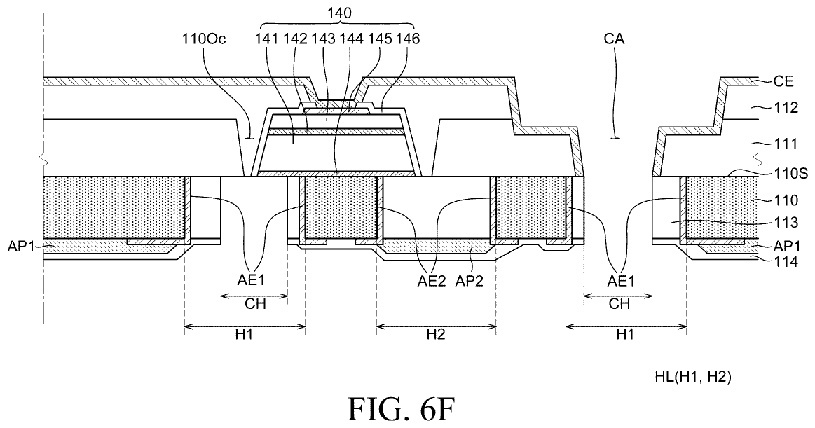

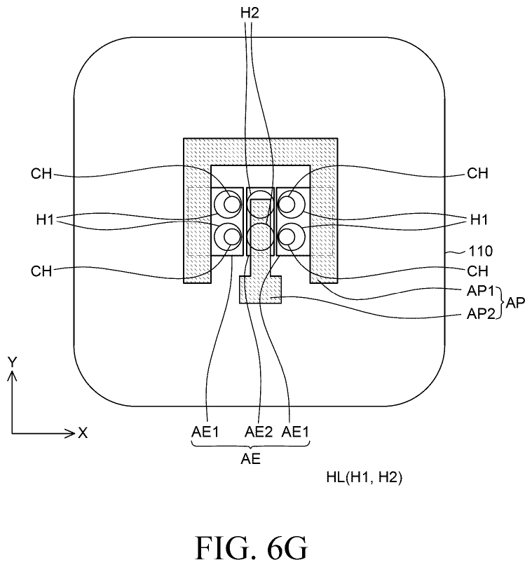

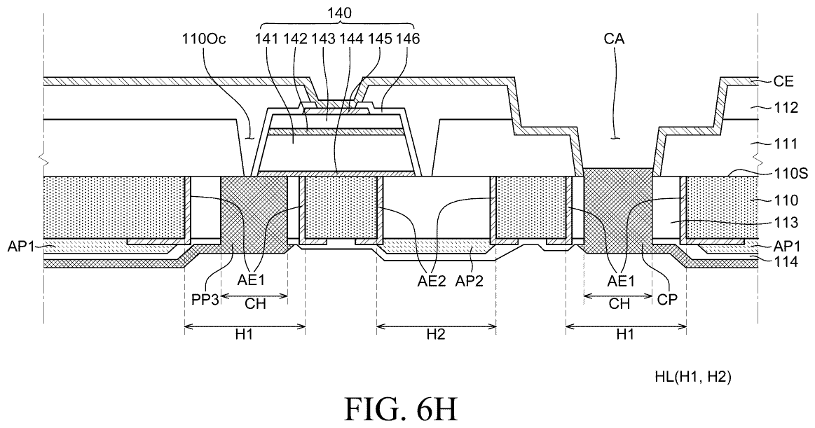

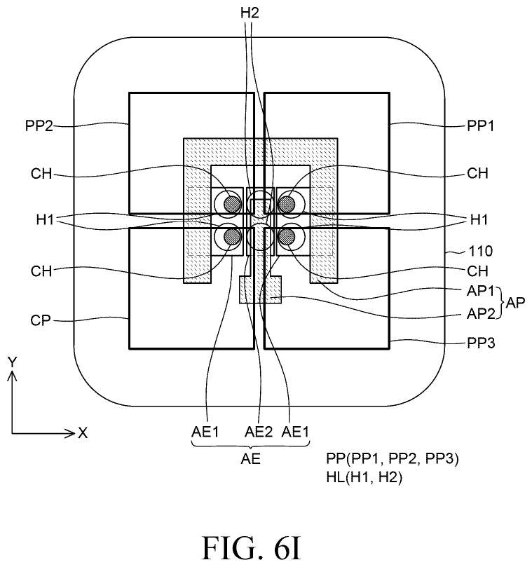

Hereinafter, a manufacturing method of a pixel unit PXU will be described with reference to FIGS. 6A to 6I.

FIGS. 6A to 6I are process diagrams for explaining a method of manufacturing a pixel unit of a display device according to an exemplary embodiment of the present disclosure.

Referring to FIG. 6A, a glass substrate is processed to form a body unit 110. An accommodation groove 110G is formed on the glass substrate and a plurality of holes HL is formed on a bottom surface 110S of the accommodation groove 110G to form the body unit 110.

Next, the plurality of assembly electrodes AE is formed in the body unit 110. A formation process of the plurality of assembly electrodes AE is performed on the rear surface of the body unit 110 to form the assembly electrode AE at the inside of the plurality of holes HL and on the rear surface of the body unit 110. The plurality of assembly electrodes AE may be formed on inner surfaces of the plurality of holes HL and on the rear surface of the body unit 110 around the plurality of holes HL. For example, the first assembly electrode AE1 extends from the rear surface of the body unit 110 toward the plurality of first holes H1 to be disposed on the rear surface of the body unit 110 and the inner surfaces of the first hole H1. The second assembly electrode AE2 extends from the rear surface of the body unit 110 toward the plurality of second holes H2 to be disposed on the rear surface of the body unit 110 and the inner surface of the second hole H2.

Referring to FIG. 6B, a filling layer 113 is formed in the plurality of holes HL. The filling layer 113 may be disposed so as to fill the plurality of holes HL and configure a plane with the bottom surface 110S of the accommodation groove 110G.

Referring to FIGS. 6C and 6D, the first planarization layer 111 is formed on the bottom surface 110S of the accommodation groove 110G. The first planarization layer 111 is formed so as to cover the front surface of the bottom surface 110S of the accommodation groove 110G and the assembly hole 111O may be formed in a position where the plurality of light emitting diodes ED is self-assembled.

The assembly pad AP is formed on the rear surface of the body unit 110. The first assembly pad AP1 may be in contact with a part of the first assembly electrode AE1 located on the rear surface of the body unit 110 and the second assembly pad AP2 may be in contact with a part of the second assembly electrode AE2 located on the rear surface of the body unit 110.

Referring to FIG. 6E, the plurality of light emitting diodes ED is self-assembled. Different AC voltages are applied to the first assembly electrode AE1 and the second assembly electrode AE2 to form an electric field. The light emitting diode ED is dielectrically polarized by the electric field to have a polarity and the dielectrically-polarized light emitting diode ED may move to a specific direction or be fixed by dielectrophoreses (DEP), that is, an electric field. Accordingly, the electric field is formed to self-assemble the plurality of light emitting diodes ED in each of the plurality of assembly holes 111O.

At this time, each of the plurality of assembly holes 111O has a planar shape corresponding to each of the plurality of light emitting diodes ED so that only the first light emitting diode 120 may be self-assembled in the first assembly hole 111Oa. Further, only the second light emitting diode 130 and the third light emitting diode 140 may be self-assembled in the second assembly hole 111Ob and the third assembly hole 111Oc, respectively.

Next, the second planarization layer 112 is formed on the plurality of light emitting diode ED. After completing the self-assembly process of the plurality of light emitting diodes ED, the second planarization layer 112 may be formed on the front surface of the accommodation groove 110G to fix and protect the plurality of light emitting diodes ED.

Referring to FIGS. 6F and 6G, the common electrode CE is formed on the second planarization layer 112. Specifically, in the contact area CA, the second planarization layer 112 and the first planarization layer 111 may be partially removed and the connection hole CH in which the common pad CP is formed may be exposed from the second planarization layer 112 and the first planarization layer 111. Further, a contact hole which exposes p-type electrodes of the plurality of light emitting diodes ED may be formed in the second planarization layer 112. Next, the common electrode CE is formed on the front surface of the second planarization layer 112 to electrically connect the common electrode CE to the p-type electrodes of the plurality of light emitting diodes ED.

Next, the passivation layer 114 is formed on the rear surface of the body unit 110 and a plurality of connection holes CH is formed. The passivation layer 114 is formed on the rear surface of the body unit 110 to cover the plurality of assembly electrodes AE, the plurality of assembly pads AP, and the filling layer 113. Next, a plurality of connection holes CH which overlaps the plurality of first holes H1, and passes through the passivation layer 114 and the filling layer 113 may be formed. The plurality of connection holes CH does not overlap the first assembly pad AP and does not allow the common pad CP and the pixel pad PP formed in the connection hole CH in a subsequent process to be connected to the plurality of assembly pads AP.

Referring to FIGS. 6H and 6I, the common pad CP and the plurality of pixel pad PP are formed. On the rear surface of the body unit 110, the common pad CP may be formed on the connection hole CH which overlaps the contact area CA. Further, on the rear surface of the body unit 110, the plurality of pixel pads PP may be formed on the connection hole CH which overlaps each of the plurality of light emitting diodes ED. The common pad CP is filled in the connection hole CH and may be connected to the common electrode CE in the accommodation groove 110G. The plurality of pixel pads PP is filled in the connection hole CH to be connected to the bottom surface of the light emitting diode ED, that is, the n-type electrode of the light emitting diode ED.

Accordingly, in the display device 100 and the manufacturing method of the display device 100 according to the exemplary embodiment of the present disclosure, the pixel unit PXU is formed as a module to easily provide the display device 100 having various sizes and shapes. Each of the plurality of pixel units PXU includes the plurality of light emitting diodes ED and the pad electrode which applies a voltage to the plurality of light emitting diodes ED to individually display images. Further, the plurality of pixel units PXU is disposed to form one display device 100. At this time, the number and arrangement of the pixel units PXU are configured in various forms to easily modify the size and the shape of the display device 100. Accordingly, the plurality of module type pixel units PXU is connected to easily form the display device 100.

In the display device 100 and the manufacturing method of the display device 100 according to the exemplary embodiment of the present disclosure, the light emitting diode ED is self-assembled in the body unit 110 to simplify the manufacturing process of the pixel unit PXU. The light emitting diode ED may be self-assembled in the assembly hole 111O of the first planarization layer 111 using an electric field between the assembly hole 111O of the first planarization layer 111 and the assembly electrode AE. Therefore, there is no need to align the light emitting diode ED in an area between the first hole H1 and the second hole H2 to be transferred, and the transfer process of the light emitting diode ED may be simplified.

In the display device 100 and the manufacturing method of the display device 100 according to the exemplary embodiment of the present disclosure, the pixel pad PP and the common pad CP for driving the light emitting diode ED are formed on the rear surface of the body unit 110. Therefore, the bezel may be reduced or minimized on the front surface of the pixel unit PXU. The pixel pad PP and the common pad CP are formed on the rear surface of the body unit 110 and are connected to the light emitting diode ED and the common electrode CE on the front surface of the body unit 110 through the connection hole CH. Accordingly, there is no need to ensure an area where the pixel pad PP and the common pad CP are disposed on the front surface of the body unit 10 so that a high resolution display device 100 with a zero-bezel may be implemented.

In the display device 100 and the manufacturing method of the display device 100 according to the exemplary embodiment of the present disclosure, the light emitting diode ED is mainly disposed on the front surface of the body unit 110 which is an emission surface to simplify the structure of the emission surface.

The exemplary embodiments of the present disclosure can also be described as follows:

According to an aspect of the present disclosure, a display device includes a plurality of pixel units disposed in a matrix, each of the plurality of pixel units includes a body unit which has an accommodation groove and a plurality of holes passing through a bottom surface of the accommodation groove, a plurality of light emitting diodes disposed in the accommodation groove, and a plurality of pixel pads which is disposed on a rear surface of the body unit and is connected to the plurality of light emitting diodes in an area of the plurality of holes, and the plurality of light emitting diode overlaps an area between the plurality of holes.

The plurality of holes may include a plurality of first holes, and a plurality of second holes disposed to be adjacent to the plurality of first holes. The display device may further include a first assembly electrode which is disposed on a rear surface of the body unit and overlaps the plurality of first holes, and a second assembly electrode which is disposed on the rear surface of the body unit and overlaps the plurality of second holes, and a part of the first assembly electrode may be disposed along inner surfaces of the plurality of first holes and the second assembly electrode is disposed along inner surfaces of the plurality of second holes.

The display device may further include a plurality of filling layers which is filled in the plurality of holes and covers the first assembly electrode and the second assembly electrode on the inner surfaces of the plurality of holes, the plurality of filling layers may configure one plane together with the bottom surface of the accommodation groove and may configure one plane together with a rear surface of the body unit.

The display device may further include a first assembly pad which is connected to the first assembly electrode on the rear surface of the body unit, and a second assembly pad which is connected to the second assembly electrode on the rear surface of the body unit.

The display device may further include a passivation layer which covers the first assembly pad, the second assembly pad, the first assembly electrode, the second assembly electrode, and the plurality of filling layers on the rear surface of the body unit.

The display device may further include a plurality of connection holes which overlaps the plurality of first holes and passes through the passivation layer and the plurality of filling layer, the plurality of connection holes may be disposed to be spaced apart from the first assembly pad.

Some of the plurality of connection holes may overlap the plurality of light emitting diodes and the plurality of pixel pads may be filled in some of the plurality of connection holes to be electrically connected to the plurality of light emitting diodes.

The display device may further include a common pad which is formed on the rear surface of the body unit and is filled in one of the plurality of connection holes, and a common electrode disposed on the plurality of light emitting diodes in the accommodation groove, the common electrode may extend toward one of the plurality of connection holes to be electrically connected to the common pad.

The display device may further include a first planarization layer which is disposed in the accommodation groove and has a plurality of assembly holes overlapping the plurality of light emitting diodes, and a second planarization layer disposed on the first planarization layer, the common electrode may be disposed on the second planarization layer.

According to an aspect of the present disclosure, a manufacturing method of a display device includes forming a body unit having a plurality of first holes, a plurality of second holes, and an accommodation groove by processing a substrate, forming a first assembly electrode and a second assembly electrode in inner surfaces of the plurality of first holes and the plurality of second holes of the body unit, respectively, forming a first planarization layer having a plurality of assembly holes in the accommodation groove, self-assembling the plurality of light emitting diodes in the plurality of assembly holes by applying a voltage to the first assembly electrode and the second assembly electrode, and forming a plurality of pixel pads and a common pad on a rear surface of the body unit.

The manufacturing method of the display device may further include after the step of forming the first assembly electrode and the second assembly electrode, a step of forming a filling layer in the plurality of first holes and the plurality of second holes.

The manufacturing method of the display device may further include before the step of forming the plurality of pixel pads and the common pad, a step of forming a passivation layer on the rear surface of the body unit, and a step of forming a plurality of connection holes which passes through the passivation layer and the filling layer, each of the plurality of pixel pads and the common pad may be filled in the plurality of connection holes.

The manufacturing method of the display device may further include a step of forming a second planarization layer which covers the plurality of light emitting diodes, a step of removing a part of the first planarization layer and the second planarization layer which overlaps a connection hole in which the common pad is filled, among the plurality of connection holes, and a step of forming a common electrode on the second planarization layer, the common pad may protrude toward the accommodation groove from the plurality of connection holes to be electrically connected to the common electrode.

Some of the plurality of connection holes may overlap the plurality of light emitting diodes and the plurality of pixel pads filled in the plurality of connection holes may be connected to lower portions of the plurality of light emitting diode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a plurality of pixel units disposed in a matrix,
wherein each of the plurality of pixel units includes:
a body unit having an accommodation groove and a plurality of holes extending through a bottom surface of the accommodation groove;
a plurality of light emitting diodes disposed in the accommodation groove; and
a plurality of pixel pads on a rear surface of the body unit and connected to the plurality of light emitting diodes through the plurality of holes, and
the plurality of light emitting diode overlaps an area between the plurality of holes.

2. The display device according to claim 1, wherein the plurality of holes includes:
a plurality of first holes; and
a plurality of second holes adjacent to the plurality of first holes,
further comprising:
a first assembly electrode on a rear surface of the body unit and overlaps the plurality of first holes; and
a second assembly electrode on the rear surface of the body unit and overlaps the plurality of second holes, and
wherein a part of the first assembly electrode is disposed along inner surfaces of the plurality of first holes and the second assembly electrode is disposed along inner surfaces of the plurality of second holes.

3. The display device according to claim 2, further comprising:
a plurality of filling layers disposed within the plurality of holes and covers the first assembly electrode and the second assembly electrode on the inner surfaces of the plurality of holes,
wherein the plurality of filling layers configures one plane together with the bottom surface of the accommodation groove and configures one plane together with a rear surface of the body unit.

4. The display device according to claim 3, further comprising:
a first assembly pad connected to the first assembly electrode on the rear surface of the body unit; and
a second assembly pad connected to the second assembly electrode on the rear surface of the body unit.

5. The display device according to claim 4, further comprising:
a passivation layer which covers the first assembly pad, the second assembly pad, the first assembly electrode, the second assembly electrode, and the plurality of filling layers on the rear surface of the body unit.

6. The display device according to claim 5, further comprising:
a plurality of connection holes which overlaps the plurality of first holes and extends through the passivation layer and the plurality of filling layer,
wherein the plurality of connection holes is disposed to be spaced apart from the first assembly pad.

7. The display device according to claim 6, wherein some of the plurality of connection holes overlaps the plurality of light emitting diodes and the plurality of pixel pads is included in some of the plurality of connection holes to be connected to the plurality of light emitting diodes.

8. The display device according to claim 6, further comprising:
a common pad on the rear surface of the body unit and disposed within one of the plurality of connection holes; and
a common electrode on the plurality of light emitting diodes in the accommodation groove,
wherein the common electrode extends toward one of the plurality of connection holes to be connected to the common pad.

9. The display device according to claim 8, further comprising:
a first planarization layer which is disposed in the accommodation groove and has a plurality of assembly holes overlapping the plurality of light emitting diodes; and
a second planarization layer on the first planarization layer,
wherein the common electrode is on the second planarization layer.

10. A manufacturing method of a display device, comprising:
forming a body unit having a plurality of first holes, a plurality of second holes, and an accommodation groove by processing a substrate;
forming a first assembly electrode and a second assembly electrode in inner surfaces of the plurality of first holes and the plurality of second holes of the body unit, respectively;
forming a first planarization layer having a plurality of assembly holes in the accommodation groove;
self-assembling the plurality of light emitting diodes in the plurality of assembly holes by applying a voltage to the first assembly electrode and the second assembly electrode; and
forming a plurality of pixel pads and a common pad on a rear surface of the body unit.

11. The manufacturing method of a display device according to claim 10, further comprising:
after forming the first assembly electrode and the second assembly electrode, forming a filling layer in the plurality of first holes and the plurality of second holes.

12. The manufacturing method of a display device according to claim 11, further comprising:
before forming the plurality of pixel pads and the common pad, forming a passivation layer on the rear surface of the body unit; and
forming a plurality of connection holes which extends through the passivation layer and the filling layer,
wherein each of the plurality of pixel pads and the common pad is filled in the plurality of connection holes.

13. The manufacturing method of a display device according to claim 12, further comprising:
forming a second planarization layer which covers the plurality of light emitting diodes;
removing a part of the first planarization layer and the second planarization layer which overlaps a connection hole in which the common pad is filled, among the plurality of connection holes; and
forming a common electrode on the second planarization layer,
wherein the common pad protrudes toward the accommodation groove from the plurality of connection holes to be connected to the common electrode.

14. The manufacturing method of a display device according to claim 12, wherein some of the plurality of connection holes overlaps the plurality of light emitting diodes and the plurality of pixel pads filled in the plurality of connection holes is connected to lower portions of the plurality of light emitting diode.
